(19) United States
(12) Patent Application Publication
(10) Pub. No.: US 2026/0344510 A1
(43) Pub. Date: Oct. 29, 2026

(54) ELECTRONIC DEVICE

(71) Applicant: Advanced Semiconductor Engineering, Inc., Kaohsiung (TW)

(72) Inventors: Kuofeng HUANG, Kaohsiung (TW); Hsin-Hua HUANG, Kaohsiung (TW); Wei Yu NIEN, Kaohsiung (TW); Hung-I LIN, Kaohsiung (TW); Chi Hao CHIANG, Kaohsiung (TW); Hsin-Chin CHANG, Kaohsiung (TW)

(73) Assignee: Advanced Semiconductor Engineering, Inc., Kaohsiung (TW)

(21) Appl. No.: 19/189,203

(22) Filed: Apr. 24, 2025

(51) Int. Cl. H10W 90/00; H10B 80/00; H10D 80/30; H10W 70/60

(52) U.S. Cl. CPC H10W 90/00; H10D 80/30; H10W 70/611; H10W 90/401; H10B 80/00; H10W 90/724

(57) ABSTRACT

The present disclosure provides an electronic device. The electronic device includes a standoff structure, a first component, a second component, and an interposer. The standoff structure defines a space. The first component is disposed within the space. The second component is disposed over the standoff structure. The interposer is disposed between the second component and the standoff structure.

### BACKGROUND

### 1. Technical Field

The present disclosure relates to an electronic device.

### 2. Description of the Related Art

Power management integrated circuits (PMICs) leverage System-in-Package (SiP) technology, including double side molding, 2.5D/3D IC, etc., to integrate multiple chips or components into a package. However, to provide different types of power control and to adapt to demands of high-speed data communication, bulky passive components may be needed. As a result, the package size may be increased, and thus the layout design flexibility may be diminished.

### SUMMARY

In some arrangements, an electronic device includes a standoff structure, a first component a second component, and an interposer. The standoff structure defines a space. The first component is disposed within the space. The second component is disposed over the standoff structure. The interposer is disposed between the second component and the standoff structure.

In some arrangements, an electronic device includes a first electronic component, a first carrier, a second carrier, a second electronic component, and a first connector. The first electronic component is disposed over the first carrier. The second carrier is disposed under the first carrier. The second electronic component is disposed over the second carrier and is configured to receive a regulated power from the first electronic component. The first connector is configured to receive a signal from an external device. The first connector is vertically spaced apart from the second carrier and laterally spaced apart from the first carrier.

In some arrangements, an electronic device includes a first electronic component, a second electronic component, a third electronic component, a first carrier, a second carrier, and a module. The first electronic component is disposed over the first carrier. The second carrier is disposed under the first carrier. The second electronic component is disposed over the second carrier and configured to receive a regulated power from the first electronic component. The third electronic component is disposed over the second carrier. The module covers the third electronic component and is electrically connected between the second carrier and an external device.

### BRIEF DESCRIPTION OF THE DRAWINGS

Aspects of some arrangements of the present disclosure are best understood from the following detailed description when read with the accompanying figures. It is noted that various structures may not be drawn to scale, and dimensions of the various structures may be arbitrarily increased or reduced for clarity of discussion.

FIG. 1 illustrates a perspective view of an electronic device, in accordance with some arrangements of the present disclosure.

FIG. 2A illustrates a cross-sectional view along line A-A′ of an electronic device as shown in FIG. 1, in accordance with some arrangements of the present disclosure.

FIG. 2B illustrates a cross-sectional view along line B-B′ of an electronic device as shown in FIG. 1, in accordance with some arrangements of the present disclosure.

FIG. 2C illustrates a cross-sectional view along line C-C′ of an electronic device as shown in FIG. 1, in accordance with some arrangements of the present disclosure.

FIG. 3A illustrates a perspective view of a signal transmitting module as shown in FIG. 1, in accordance with some arrangements of the present disclosure.

FIG. 3B illustrates an exploded view of the signal transmitting module, in accordance with some arrangements of the present disclosure.

FIG. 4 illustrates a cross-sectional view of an electronic device, in accordance with some arrangements of the present disclosure.

FIG. 5 illustrates a cross-sectional view of an electronic device, in accordance with some arrangements of the present disclosure.

FIG. 6 illustrates a cross-sectional view of an electronic device, in accordance with some arrangements of the present disclosure.

FIG. 7 illustrates a cross-sectional view of an electronic device, in accordance with some arrangements of the present disclosure.

FIG. 8 illustrates a cross-sectional view of an electronic device, in accordance with some arrangements of the present disclosure.

### DETAILED DESCRIPTION

The following disclosure provides for many different arrangements, or examples, for implementing different features of the provided subject matter. Specific examples of components and arrangements are described as follows to explain certain aspects of the present disclosure. These are, of course, merely examples and are not intended to be limiting. For example, the formation of a first feature over or on a second feature in the description that follows may include arrangements in which the first and second features are formed or disposed in direct contact, and may also include arrangements in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various arrangements and/or configurations discussed.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of arrangements of this disclosure are not deviated from by such arrangement.

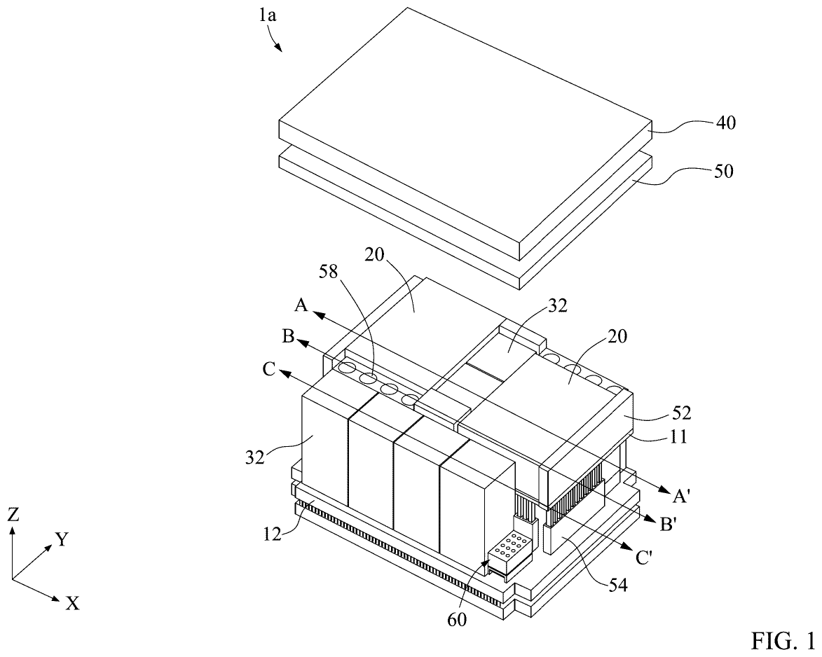

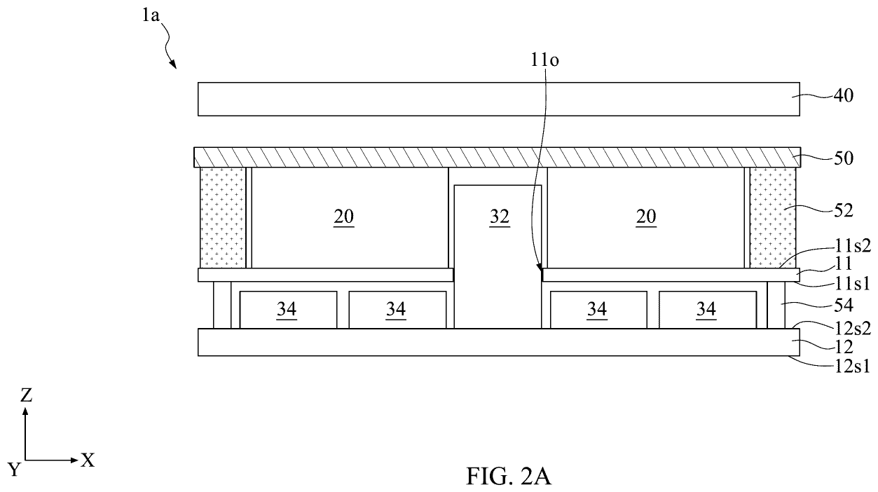

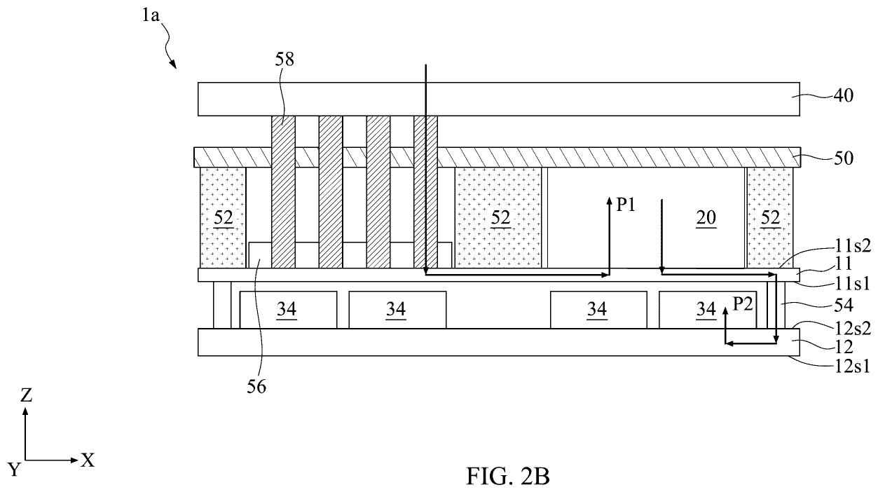

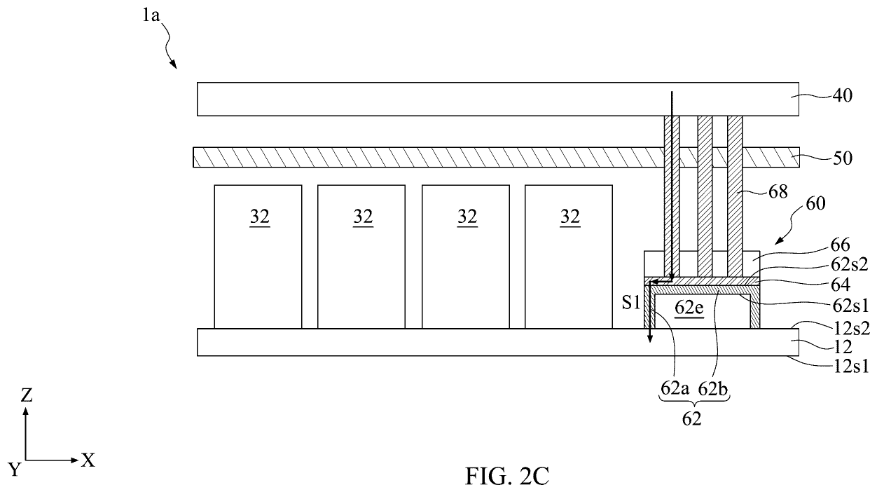

FIGS. 1 and 2A-2C illustrate an electronic device 1a, in accordance with some arrangements of the present disclosure. In some arrangements, the electronic device 1a may include carriers 11 and 12, electronic components 20, 32, and 34, a circuit structure 40, a heat dissipating structure 50, as well as a signal transmitting module 60.

As shown in FIGS. 1 and 2A, each of the carriers 11 and 12 may be formed as a printed circuit board (PCB), flexible printed circuit board (FPCB), lead frame, a combination thereof, or other suitable circuit structures. The carriers 11 and 12 may be at different levels (or elevation or height) along the Z direction. Each of the carriers 11 and 12 may include multiple metal layers separated from one another by layers of dielectric material and interconnected by electrically conductive vias. In some embodiments, each of the carriers 11 and 12 may be formed of an epoxy resin, a fiberglass-reinforced epoxy resin, an epoxy resin with inorganic fillers, a ceramic material, or a polymer material such as polyimide. The carrier 11 may have a surface 11s1 (or lower surface) and a surface 11s2 (or upper surface) opposite to the surface 11s1. The carrier 12 may have a surface 12s1 (or lower surface) and a surface 12s2 (or upper surface) opposite to the surface 12s1. The carrier 11 may be disposed over the surface 12s2 of the carrier 12. In some arrangements, the carrier 11 may have a dimension (e.g., surface area along the XY plane) less than that of the carrier 12. In some arrangements, a portion of the surface 12s2 of the carrier 12 may be exposed by the carrier 11.

The electronic component 20 may be disposed on or over the surface 11s2 of the carrier 11. In some arrangements, the electronic component 20 may function as a first stage power module (or first power conversion stage or converter or electrical converter). In some arrangements, the electronic component 20 may be configured to convert a higher voltage (e.g., 48 V) to a lower voltage (e.g., 12 V). For example, the electronic component 20 may be configured to receive a higher voltage from the circuit structure 40 and transmit a lower voltage to the electronic component 32 (or electronic component 34). In some arrangements, the electronic component 20 may include at least one power module (or converter), which includes a transistor(s), a diode(s), a capacitor(s), an inductor(s), and/or other suitable elements. For example, the electronic component 20 may include a circuit structure formed as a PCB, FPCB, or other suitable circuit structures. The active components (e.g., converters, controllers, and/or drivers) and passive components (e.g., capacitors and/or inductors) may be disposed on the circuit structure.

The electronic components 32 and 34 may be disposed on or over the surface 12s2 of the carrier 12. Each of the electronic components 32 and 34 may function as a second stage power module (or second power conversion stage or converter or electrical converter). In some arrangements, each of the electronic components 32 and 34 may be configured to convert a higher voltage (e.g., 12 V) to a lower voltage (e.g., 8 V, 6 V, 4 V, 2 V, or less). In some arrangements, the electronic components 32 and 34 may have different thicknesses along the Z direction. The electronic components 32 and 34 may be electrically connected to the carrier 11. The electronic components 32 and 34 may be electrically connected to the carrier 12. The electronic components 32 and 34 may include multiple elements on a circuit structure (e.g., PCB). For example, the electronic components 32 and 34 may include a transistor(s), a controller(s), and a passive element(s). It should be noted that the electronic device 1a may include more components between the carriers 11 and 12. For example, the electronic device 1a may include a controller configured to turn on or turn off the electronic component 32 and/or 34. The electronic components 32 and 34 may include multiple elements on a circuit structure (e.g., PCB). For example, the electronic components 32 and 34 may include a transistor(s), a controller(s), and a passive element(s). In some arrangements, each of the electronic components 32 and 34 may also be referred to as a voltage regulator or power block.

In some arrangements, the electronic component 32 may be partially disposed within an opening 11o defined by the carrier 11. In some arrangements, a portion of the electronic component 32 may be protruded from the surface 11s2 of the carrier 11. In some arrangements, the thickness (e.g., the length along the Z direction) of the electronic component 32 may be greater than that of the electronic component 20. The electronic component 34 may be disposed within a space defined by the carriers 11 and 12. In some arrangements, the electronic component 34 may have a thickness (e.g., the length along the Z direction) less than that of the electronic component 20. In some arrangements, the thickness of the electronic component 32 may be greater than or equal to 7 mm, such as 7 mm, 8 mm, 9 mm, 10 mm, or more. In some arrangements, the thickness of the electronic component 20 may range between 3 mm and 7 mm, such as 3 mm, 4 mm, 5 mm, 6 mm, or 7 mm. The thickness of the electronic component 34 may range between about 1 mm and 5 mm, such as 1 mm, 2 mm, 3 mm, 4 mm, or 5 mm.

In some arrangements, the circuit structure 40 (or power delivery board) may be disposed on or over the surface 11s2 of the carrier 11. In some arrangements, the circuit structure 40 may be configured to provide the electronic component 20 with a relatively great power (e.g., 48 V). In some arrangements, the circuit structure 40 may be configured to transmit a signal (e.g., non-power signal or data signal) to the carrier 12. In some arrangements, the circuit structure 40 may include a PCB, FPCB, or other suitable circuit structures. One or more electronic components (not shown) may be disposed on or over the circuit structure 40. For example, the electronic device 1a may include a power management integrated circuit (PMIC) die on or within the circuit structure 40. In this disclosure, the circuit structure 40 may also be referred to as an external device.

In some arrangements, the heat dissipating structure 50 may be disposed between the electronic component 20 and the circuit structure 40. In some arrangements, the heat dissipating structure 50 may be thermally coupled to the electronic component 20. For example, the heat dissipating structure 50 may be configured to transmit heat from the electronic component 20. In some arrangements, the heat dissipating structure 50 may be thermally coupled to the circuit structure 40. For example, the heat dissipating structure 50 may be configured to transmit heat from the circuit structure 40. In some arrangements, the heat dissipating structure 50 may be in contact with the electronic component 20. In some arrangements, the heat dissipating structure 50 may be spaced apart from the electronic component 20 by a thermal interface material (TIM) or adhesive. The heat dissipating structure 50 may include a cold plate, which may include a vapor chamber, heat pipe, and/or other suitable elements. The heat dissipating structure 50 may include thermal conductive materials, such as aluminum (Al), copper (Cu), chromium (Cr), tin (Sn), gold (Au), silver (Ag), nickel (Ni) or stainless steel, or a mixture, an alloy, or other combinations thereof.

In some arrangements, the electronic device 1a may include blocks 52. The blocks 52 may be disposed on or over the surface 11s2 of the carrier 11. In some arrangements, the blocks 52 may function as a spacer configured to adjust a distance between the heat dissipating structure 50 and the carrier 11. In some arrangements, the blocks 52 may be configured to be thermally coupled to the electronic component 20. The blocks 52 may include thermal conductive materials, such as aluminum (Al), copper (Cu), chromium (Cr), tin (Sn), gold (Au), silver (Ag), nickel (Ni) or stainless steel, or a mixture, an alloy, or other combinations thereof.

In some arrangements, the electronic device 1a may include interconnections 54. In some arrangements, the interconnections 54 may be disposed on or over the surface 12s2 of the carrier 12. The interconnections 54 may be disposed at a peripheral region of the carrier 12. For example, the interconnections 54 may surround the electronic components 32 and 34. The interconnections 54 may be disposed between the carriers 11 and 12. In some arrangements, the interconnections 54 may be configured to support the carrier 11. In some arrangements, the interconnections 54 may electrically connect the carriers 11 and 12. In some arrangements, the interconnections 54 may be configured to transmit power and/or signal. In some arrangements, the interconnections 54 may include a pogo pin, conductive pillar, or other suitable conductive elements. In other arrangements, the interconnections 54 may be replaced by an interposer(s), which may include a substrate (e.g., silicon substrate or other substrate) and conductive elements (e.g., through silicon via (TSV)) in the substrate. In other arrangements, the interconnections 54 may be replaced by other conductive components, such as solder materials.

As shown in FIGS. 1 and 2B, the electronic device 1a may include a connector 56 and conductive elements 58. In some arrangements, the connector 56 may be disposed on or over the surface 11s2 of the carrier 11. In some arrangements, the connector 56 may be configured to connect, hold, or accommodate the conductive elements 58. For example, the connector 56 may define a recess for accommodating a portion of the conductive elements 58. In some arrangements, the conductive elements 58 may be connected between the carrier 11 and the circuit structure 40. The conductive elements 58 may be disposed on or over the surface 11s2 of the carrier 11. In some arrangements, the conductive elements 58 may be configured to transmit power (or power signal) between the electronic component 20 and circuit structure 40. For example, the conductive elements 58 may be configured to transmit a relatively great power (e.g., 48 V) from the circuit structure 40 to the electronic component 20. In some arrangements, the conductive elements 58 may penetrate the heat dissipating structure 50. In some arrangements, the conductive elements 58 may include a pogo pin, conductive pillar, or other suitable conductive elements. As shown in FIG. 2B, the circuit structure 40 may be configured to provide the electrical path (or power path) conducting power P1 (e.g., 48V) to the electronic component 20 through the conductive elements 58 and carrier 11. In some arrangements, the carriers 11 and 12 and interconnections 54 may be configured to provide the electrical path (or power path) conducting power P2 (e.g., 12V) from the electronic component 20 to the electronic component 34. Similarly, the electronic component 32 may be configured to receive the power (e.g., 12V) through the carriers 11 and 12 and interconnections 54 from the electronic component 20.

As shown in FIGS. 1 and 2C, the signal transmitting module 60 (or module) may be disposed on or over the surface 12s2 of the carrier 12. In some arrangements, the signal transmitting module 60 may be configured to receive and/or transmit a signal (or non-power signal). For example, the signal transmitting module 60 may be configured to receive and/or transmit a signal between the carrier 12 and the circuit structure 40. In some arrangements, the signal transmitting module 60 may be exposed by the carrier 11. In some arrangements, the signal transmitting module 60 may be free from vertically overlapping the carrier 11 or free from overlapping the carrier 11 along the Z direction. In some arrangements, the signal transmitting module 60 may include a standoff structure 62, an interposer 64, a connector 66, and conductive elements 68.

In some arrangements, the standoff structure 62 may be disposed over or attached to the surface 12s2 of the carrier 12. In some arrangements, the standoff structure 62 may be configured to transmit a signal (or non-power signal). In some arrangements, the standoff structure 62 may be configured to support the interposer 64 and the connector 66. In some arrangements, the standoff structure 62 may function as a spacer and be configured to separate the connector 66 from the carrier 12. The standoff structure 62 may have supporting portions 62a and a plate 62b supported by the supporting portions 62a. The standoff structure 62 may have a surface 62s1 and a surface 62s2 on the two opposite sides of the plate 62b. In some arrangements, the standoff structure 62 may be configured to define a space 62e extending between the surface 62s1 of the standoff structure 62 and surface 12s2 of the carrier 12.

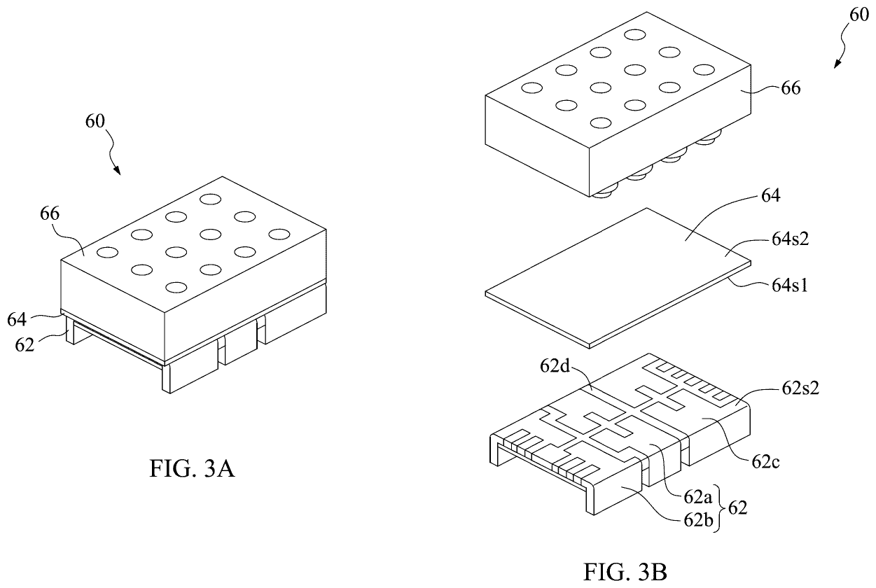

Please refer to FIGS. 3A and 3B, the standoff structure 62 may include a lead frame, which may include a conductive pattern 62c and an insulating portion 62d encapsulating the conductive pattern 62c.

The interposer 64 may be disposed on or over the surface 62s2 of the standoff structure 62. The interposer 64 may be electrically connected between the standoff structure 62 and connector 66. In some cases, the profile of the conductive pattern 62c is designed to have supporting functions and cannot match the pattern of the connector 66 (or conductive elements 68), and the interposer 64 may function as a pattern-matching structure, which is configured to match the standoff structure 62 and connector 66 that have different conductive patterns and pattern densities (or terminal densities). For example, the interposer 64 may be designed to have a pattern which is more complex than that of the standoff structure 62. The interposer 64 may have a surface 64s1 (or a lower surface) facing the standoff structure 62 and a surface 64s2 (or an upper surface) facing the connector 66. In some arrangements, the conductive pattern on the surface 64s1 may have a pattern density different from that of the conductive pattern on the surface 64s2. In some arrangements, the interposer 64 may include a PCB, FPCB, or other suitable circuit structures.

The connector 66 may be disposed on or over surface 64s2 of the interposer 64. In some arrangements, the connector 66 may be configured to connect, hold, or accommodate the conductive elements 68. For example, the connector 66 may define a recess for accommodating a portion of the conductive elements 68. In some arrangements, the connector 66 may have a level (or height or elevation) between the carriers 11 and 12. In some arrangements, the connector 66 may have a level (or height or elevation) greater than that of the surface 11s2 of the carrier 11 with respect to the surface 12s2 of the carrier 12. In some arrangements, the connector 66 may have a level (or height or elevation) less than that of the connector 56 with respect to the surface 12s2 of the carrier 12. The end (or upper surface) of the electronic component 32 may extend beyond the connector 66.

Please refer back to FIG. 2C, the conductive elements 68 may be connected between the carrier 12 and the circuit structure 40. The conductive elements 68 may be disposed on or over the surface 12s2 of the carrier 12. In some arrangements, the conductive elements 68 may be configured to transmit signal between the carrier 12 and the circuit structure 40. In some arrangements, the conductive elements 68 may penetrate the heat dissipating structure 50. In some arrangements, the conductive elements 68 may include a pogo pin, conductive pillar, or other suitable conductive elements. As shown in FIG. 2C, the signal transmitting module 60 may be configured to provide the electrical path (or signal path) conducting a signal S1 from the circuit structure 40 to the carrier 12.

In some cases, the conductive elements 68 may become tilted if their lengths surpass a specific threshold. To address this issue, the elevation of the connector 66 can be adjusted using the standoff structure 62, which effectively shortens the lengths of the conductive elements 68. Consequently, this adjustment enhances the overall robustness of the electronic device 1a, thereby minimizing the risk of collapse of the conductive elements 68.

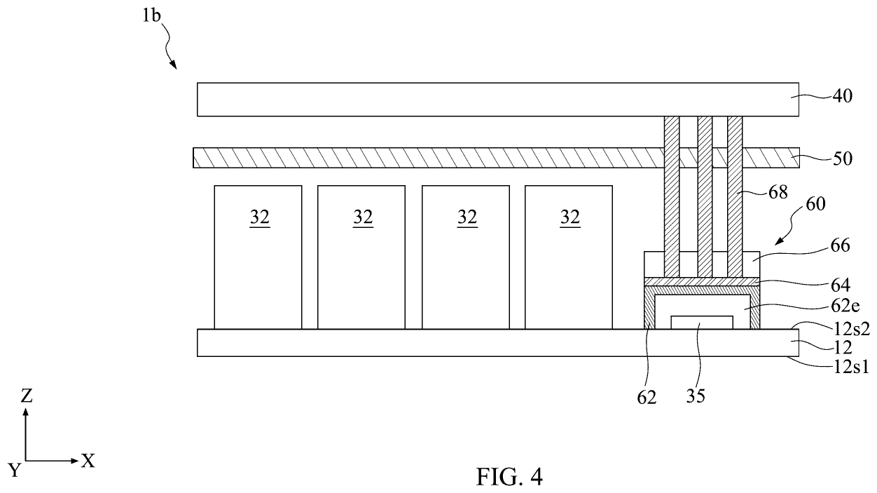

FIG. 4 illustrates a cross-sectional view of an electronic device 1b, in accordance with some arrangements of the present disclosure. The electronic device 1b is similar to the electronic device 1a, differing as follows.

In some arrangements, the electronic device 1b may include an electronic component 35. The electronic component 35 may be disposed on or over the surface 12s2 of the carrier 12. In some arrangements, the electronic component 35 may be disposed within the space 62e of the standoff structure 62. In some arrangements, the electronic component 35 may have a dimension (e.g., the thickness along the Z direction) less than that of the electronic component 32. In some arrangements, the electronic component 35 may have a dimension (e.g., the thickness along the Z direction) less than that of the electronic component 34 as shown in FIG. 2B. In some arrangements, the electronic component 35 may vertically overlap or be covered by the signal transmitting module 60. For example, the electronic component 35 may vertically overlap or be covered by the standoff structure 62. The electronic component 35 may vertically overlap or be covered by the connector 66. In some arrangements, the electronic component 35 may be free from vertically overlapping the carrier 11. In some arrangements, the electronic component 35 may be laterally spaced apart from the electronic component 32 by the standoff structure 62 or spaced apart from the electronic component 32 by the standoff structure 62 along the XY plane. In some arrangements, the electronic component 35 may include a power monitor, which is configured to monitor the regulated power from the electronic component 20 or the regulated power from the electronic component 32 (or electronic component 34). In some arrangements, the electronic component 35 may be configured to receive the signal through the standoff structure 62, the interposer 64, and the connector 66. In some arrangements, the electronic component 35 may include a voltage regulator or converter, which is configured to convert a higher voltage (e.g., 12 V) to a lower voltage (e.g., 8 V, 6 V, 4 V, 2 V, or less). In some arrangements, the electronic component 35 may include a component which has other functions. For example, the electronic component 35 may be configured to turn on or turn off the electronic component 32 (or electronic component 34). In some arrangements, the electronic component 35 may include a passive device (e.g., capacitor) which is configured to regulate the power from the electronic component 20, 34, and/or 32.

In a comparative example, a power transmission converter and a connector may be directly mounted on a carrier. In this configuration, certain components, such as power modules and/or switches, will occupy additional space on the carrier. In this arrangement, the electronic component 35 is positioned within the space 62e, which is designed to accommodate components with relatively small dimensions. Consequently, the electronic component 35 and connector 66 together occupy a smaller area (e.g., the surface area along the XY plane) of the carrier 12 compared to the comparative example.

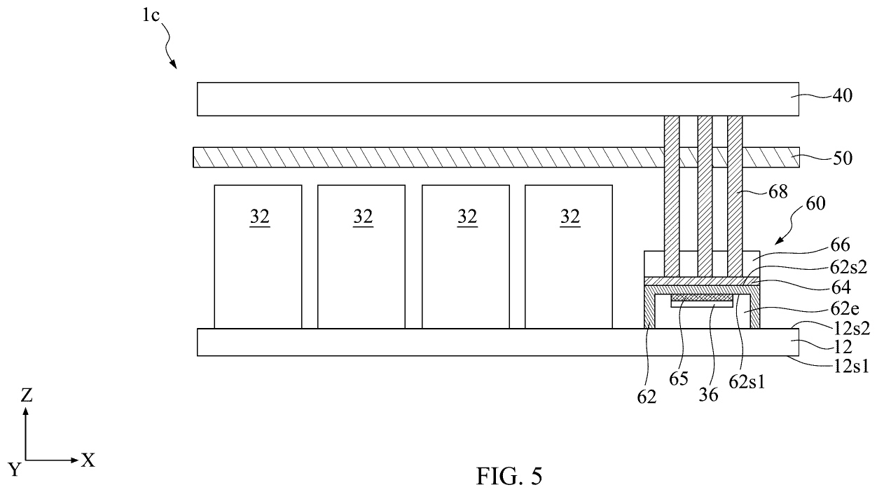

FIG. 5 illustrates a cross-sectional view of an electronic device 1c, in accordance with some arrangements of the present disclosure. The electronic device 1c is similar to the electronic device 1a, differing as follows.

In some arrangements, the electronic device 1c may include an electronic component 36. The electronic component 36 may be disposed on or under the surface 62s1 of the standoff structure 62. In some arrangements, the electronic component 36 may be disposed within the space 62e of the standoff structure 62. In some arrangements, the electronic component 36 may be spaced apart from the carrier 12. In some arrangements, the electronic component 36 may have functions similar to or the same as those of the electronic component 35. For example, the electronic component 36 may include a power monitor, voltage regulator, controller, or other suitable components.

In some arrangements, the electronic component 36 may be electrically connected to the standoff structure 62 by an interposer 65. In some arrangements, the interposer 65 may function as a pattern-matching structure, which is configured to match the electronic component 36 and standoff structure 62 that have different conductive patterns and pattern densities (or terminal densities). In some arrangements, the interposer 65 may include a PCB, FPCB, or other suitable circuit structures.

In this arrangement, the electronic component 36 may be disposed within the space 62e without occupying additional areas, thereby reducing the surface area (e.g., the surface area along the XY plane) of the carrier 12.

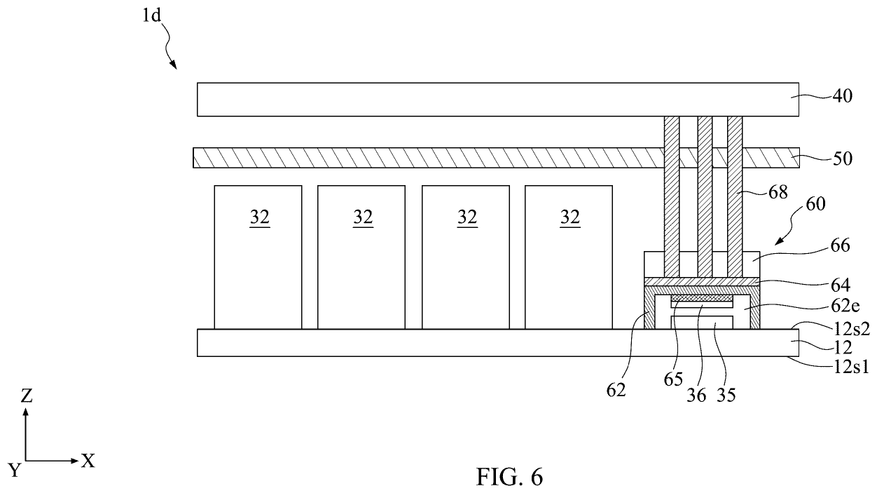

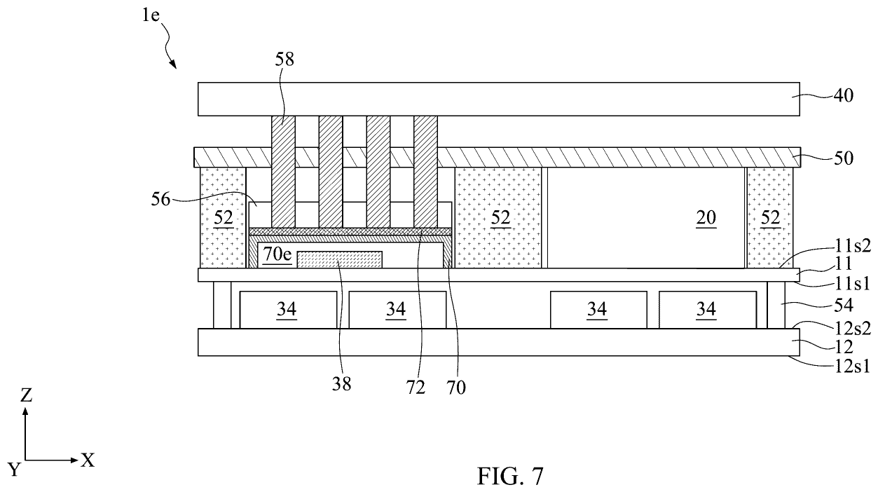

FIG. 6 illustrates a cross-sectional view of an electronic device 1d, in accordance with some arrangements of the present disclosure. The electronic device 1d is similar to the electronic device 1a, differing as follows.

In some arrangements, two or more components may be disposed within the space 62e and vertically overlap each other. For example, the electronic device 1d may include the electronic components 35 and 36. The electronic component 35 may vertically overlap the electronic component 36. In this arrangement, the electronic components 35 and 36 may be disposed within the space 62e without occupying additional areas, thereby reducing the surface area (e.g., the surface area along the XY plane) of the carrier 12.

FIG. 7 illustrates a cross-sectional view of an electronic device 1e, in accordance with some arrangements of the present disclosure. The electronic device 1e is similar to the electronic device 1a, differing as follows.

In some arrangements, the electronic device 1e may include a standoff structure 70 and an interposer 72. In some arrangements, the standoff structure 70 may be attached to the surface 11s2 of the carrier 11. In some arrangements, the standoff structure 70 may have a structure the same as or similar to that of the standoff structure 62 as shown in FIG. 2C. In some arrangements, the standoff structure 70 may be configured to transmit power (or power signal). In some arrangements, the standoff structure 70 may be configured to support the connector 56 and the conductive elements 58. In some arrangements, the standoff structure 70 may be configured to separate the connector 56 from the carrier 11. In some arrangements, the standoff structure 70 may be configured to define a space 70e.

The interposer 72 may be electrically connected between the connector 56 and standoff structure 70. In some arrangements, the interposer 72 may function as a pattern-matching structure, which is configured to match the connector 56 and standoff structure 70 that have different conductive patterns and pattern densities (or terminal densities). In some arrangements, the interposer 72 may include a PCB, FPCB, or other suitable circuit structures.

In some arrangements, the electronic device 1e may include an electronic component 38. In some arrangements, the electronic component 38 may be disposed within the space 70e. For example, the electronic component 38 may include a power monitor, voltage regulator, controller, passive devices (e.g., capacitors) or other suitable components. In this arrangement, the electronic component 38 may be disposed within the space 70e without occupying additional areas, thereby reducing the surface area (e.g., the surface area along the XY plane) of the carrier 11 and/or 12.

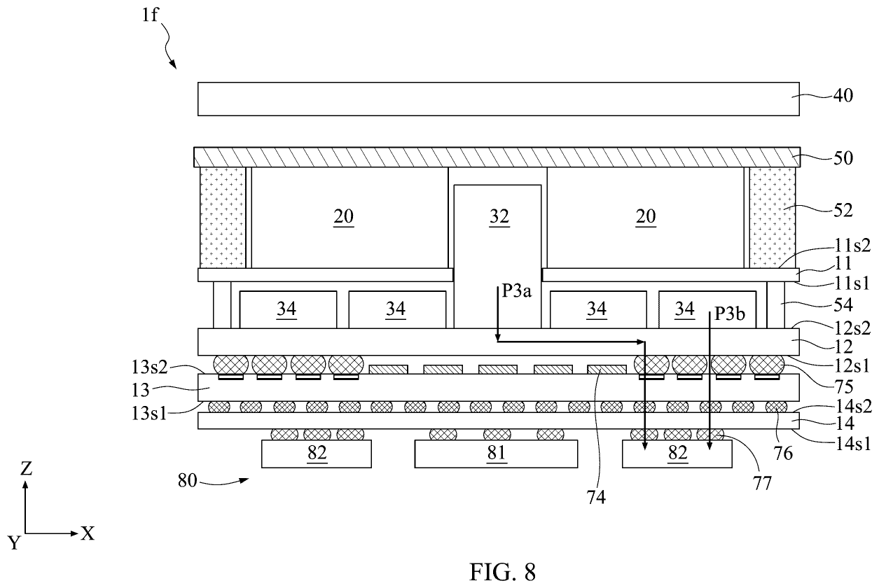

FIG. 8 illustrates a cross-sectional view of an electronic device 1f, in accordance with some arrangements of the present disclosure. The electronic device 1f is similar to the electronic device 1a, differing as follows.

In some arrangements, the electronic device 1f may include a carrier 13. In some arrangements, the carrier 13 may be formed as a printed circuit board, flexible printed circuit board, or other suitable circuit structures. The carrier 13 may include multiple metal layers separated from one another by layers of dielectric material and interconnected by electrically conductive vias. In some embodiments, the carrier 13 may be formed of an epoxy resin, a fiberglass-reinforced epoxy resin, an epoxy resin with inorganic fillers, a ceramic material, or a polymer material such as polyimide. The carrier 13 may have a surface 13s1 (or lower surface) and a surface 13s2 (or upper surface) opposite to the surface 13s1. The surface 13s2 of the carrier 13 may face the surface 12s1 of the carrier 12.

In some arrangements, the electronic device 1f may include passive components 74. The passive components 74 may be disposed on or over the surface 13s2 of the carrier 13. In some arrangements, the passive components 74 may be disposed between the carriers 12 and 13. The passive components 74 may be electrically connected to the carrier 13. In some arrangements, the passive components 74 may be configured to regulate the power from the electronic component 32 or (or electronic component 34) toward an operating module 80 (or computing module). In some arrangements, the passive components 74 may include capacitors. In some arrangements, the passive components 74 may include input capacitors (Cin) through which the power flows before being delivered to the electronic component 32 (or electronic component 34). In some arrangements, the passive components 74 may include output capacitors (Cout) through which the power flows after being transmitted from the electronic component 32 (or electronic component 34).

The electronic device 1f may include electrical connectors 75. The electrical connectors 75 may be between the carriers 12 and 13. The electrical connectors 75 may be or include electrical contacts, such as solder balls (e.g., controlled collapse chip connection (C4) bumps, a ball grid array (BGA), a land grid array (LGA)), conductive bumps, or the like. The electrical connectors 75 may include alloys of gold and tin solder or alloys of silver and tin solder, or other suitable materials.

The electronic device 1f may include a carrier 14 (or substrate). In some arrangements, the carrier 14 may be disposed on or under the surface 13s1 of the carrier 13. In some arrangements, the carrier 14 may include a semiconductor substrate, such as silicon, germanium, and other group III-V and group IV materials. The carrier 14 may include metal lines and vias, including but not limited to through-silicon vias (TSVs) for interconnection. In some arrangements, the carrier 14 may include a wafer, a panel form or other suitable forms. The carrier 14 may have a surface 14s1 (or a lower surface) and a surface 14s2 (or an upper surface) opposite to the surface 14s1.

The carrier 14 may be electrically connected to the carrier 13 through electrical connectors 76. The carrier 14 may be configured to support the operating module 80. In some arrangements, the electrical connectors 76 may include a reflowable material. The electrical connectors 76 may be or include electrical contacts, such as solder balls (e.g., controlled collapse chip connection (C4) bumps, a ball grid array (BGA), a land grid array (LGA)), conductive bumps, or the like. The electrical connectors 76 may include alloys of gold and tin solder or alloys of silver and tin solder, or other suitable materials.

In some arrangements, the operating module 80 may be disposed on or under the surface 14s1 of the carrier 14. In some arrangements, the operating module 80 may be configured to generate non-power signals, such as analog signals, digital signals, clock signals, or other electrical signals. The operating module 80 may include electronic components 81 and 82. In some arrangements, the electronic components 81 and 82 may be disposed on or under the surface 14s1 of the carrier 14. In some arrangements, the electronic component 81 may include a processor or other suitable components. In some arrangements, the electronic component 81 may include an active device, such as a central processing unit (CPU), a microprocessor unit (MPU), a graphics processing unit (GPU), a microcontroller unit (MCU), a radio frequency integrated circuit (RFIC), an application-specific IC (ASIC), a field-programmable gate array (FPGA), or another type of IC. In some arrangements, the electronic component 82 may include a data storage unit or other suitable components. The electronic component 82 may be electrically connected to the electronic component 81 through the carrier 14. The electronic component 82 may be disposed on or under the surface 14s1 of the carrier 14. In some arrangements, the electronic component 82 may be configured to store the signals from the electronic component 81 and/or other devices. In some arrangements, the electronic component 82 may include a high band memory (HBM) die, dynamic random access memory (DRAM) die, static random access memory (SRAM) die, or other suitable memory devices. In some arrangements, the operating module 80 may further include other components, such as input/output dies configured to receive regulated power from the electronic component 32 (or electronic component 34) and/or transmit a processed signal to other devices (not shown). The electronic components 81 and 82 may be electrically connected to the carrier 14 by electrical connectors 77. In some arrangements, the electrical connectors 77 may include a reflowable material. The electrical connectors 77 may be or include electrical contacts, such as solder balls (e.g., controlled collapse chip connection (C4) bumps, a ball grid array (BGA), a land grid array (LGA)), conductive bumps, or the like. The electrical connectors 77 may include alloys of gold and tin solder or alloys of silver and tin solder, or other suitable materials. In other arrangements, the electronic components 81 and 82 may be electrically connected to the carrier 14 by hybrid-bond techniques, which involve a bonding between metallic materials (e.g., a bonding between copper and copper) and a bonding between dielectric materials (e.g., a bonding between oxide and oxide).

The operating module 80 may be configured to receive powers P3a and P3b (or regulated powers) from the electronic components 32 and 34, respectively. In some arrangements, the carrier 12 may be configured to provide the electrical path (or power path) conducting the powers P3a and P3b. In some arrangements, the carrier 13 may be configured to provide the electrical path (or power path) conducting the powers P3a and P3b. In some arrangements, the carrier 14 may be configured to provide the electrical path (or power path) conducting the powers P3a and P3b. In some arrangements, the electronic components 32 and 34 may provide the operating module 80 with powers at different levels (e.g., 8 V, 6 V, 4 V, 2 V, or less). For example, the power P3a may be different from the power P3b.

As used herein, the singular terms “a,” “an,” and “the” may include a plurality of referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific arrangements thereof, these descriptions and illustrations do not limit the present disclosure. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other arrangements of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic device, comprising:
a standoff structure defining a space;
a first component disposed within the space;
a second component disposed over the standoff structure; and
an interposer disposed between the second component and the standoff structure.

2. The electronic device of claim 1, wherein the standoff structure is electrically connected to the second component by the interposer.

3. The electronic device of claim 1, wherein the interposer has a first pattern on a first surface facing the standoff structure and a second pattern on a second surface facing the second component, and a pattern density of the first pattern is different from a pattern density of the second pattern.

4. The electronic device of claim 1, wherein the second component is configured to receive a signal.

5. The electronic device of claim 4, wherein the second component is configured to receive the signal which is transmitted along a direction from the second component toward the first component.

6. The electronic device of claim 5, wherein the first component is configured to receive the signal through the standoff structure, the interposer, and the second component.

7. The electronic device of claim 1, wherein the second component comprises a connector configured to accommodate a conductive element transmitting a signal.

8. The electronic device of claim 1, further comprising:
a first carrier having a first region supporting the first component and a second region distinct from the first region; and
a second carrier disposed over the second region of the first carrier.

9. The electronic device of claim 8, further comprising:
a voltage regulator disposed over the first region of the first carrier, wherein an end of the voltage regulator extends upwardly and beyond the second carrier.

10. An electronic device, comprising:
a first electronic component disposed over a first carrier;
a second carrier disposed under the first carrier;
a second electronic component disposed over the second carrier and configured to receive a regulated power from the first electronic component; and
a first connector configured to receive a signal from an external device,
wherein the first connector is vertically spaced apart from the second carrier and laterally spaced apart from the first carrier.

11. The electronic device of claim 10, further comprising:
a standoff structure electrically connected between the second carrier and the first connector.

12. The electronic device of claim 11, further comprising:
a power monitor disposed over the second carrier and covered by the standoff structure.

13. The electronic device of claim 12, wherein the power monitor is spaced apart from the second electronic component by the standoff structure.

14. The electronic device of claim 10, further comprising:
a second connector disposed over the first carrier and configured to transmit a power to the first electronic component.

15. The electronic device of claim 14, wherein an elevation of the first connector is less than an elevation of the second connector with respect to the second carrier.

16. An electronic device, comprising:
a first electronic component disposed over a first carrier;
a second carrier disposed under the first carrier;
a second electronic component disposed over the second carrier and configured to receive a regulated power from the first electronic component;
a third electronic component disposed over and electrically connected to the second carrier; and
a module covering the third electronic component and electrically connected between the second carrier and an external device.

17. The electronic device of claim 16, wherein the module is configured to transceive a signal between the external device and the second carrier.

18. The electronic device of claim 16, wherein the module comprises a standoff structure attached to the second carrier and covering the third electronic component.

19. The electronic device of claim 18, wherein the module comprises a first connector configured to accommodate a conductive element transmitting a signal.

20. The electronic device of claim 19, wherein the module comprises a pattern-matching structure electrically connected between the standoff structure and the first connector.
